(19) United States
(12) Patent Application Publication
(10) Pub. No.: US 2026/0110109 A1
(43) Pub. Date: Apr. 23, 2026

(54) VENTED SEMICONDUCTOR PROCESSING CHAMBER

(71) Applicant: Applied Materials, Inc., Santa Clara, CA (US)

(72) Inventors: Raja Murali DHAMODHARAN, Madurai (IN); Shainish NELLIKKA, Bangalore (IN); Youngki CHANG, Santa Clara, CA (US); Manjunath SUBBANNA, Bangalore (IN)

(21) Appl. No.: 18/920,364

(22) Filed: Oct. 18, 2024

(51) Int. Cl. C30B 25/14; C30B 25/08; C30B 25/10; C30B 25/16

(52) U.S. Cl. CPC C30B 25/14; C30B 25/08; C30B 25/10; C30B 25/165

(57) ABSTRACT

Embodiments of the present disclosure relate to an apparatus for processing a substrate. A processing chamber includes a chamber body. The chamber body includes an upper body, a lower body, a carrier and feed (CF) ring disposed between the upper body and the lower body, an upper liner, a lower liner, and a substrate support. The lower liner includes an upper venting liner. The upper venting liner includes one or more upper vents, and an internal volume. The internal volume includes a processing volume, and a purge volume. The substrate support is disposed within the internal volume. The upper venting liner is disposed below the substrate support.

### CROSS-REFERENCE TO RELATED APPLICATIONS

This application claims benefit of Indian provisional patent application serial number 202341071725, filed Aug. 20, 2023, which is herein incorporated by reference.

### BACKGROUND

### Field

Embodiments of the present disclosure generally relate to apparatus and systems for semiconductor processing. In particular, the present disclosure is directed towards epitaxial deposition chambers.

### Description of the Related Art

Semiconductor substrates are processed for a wide variety of applications, including the fabrication of integrated devices and micro-devices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate. For example, the migration of purge gas from a purge volume to a processing volume of the processing chamber can affect deposition uniformity. It may be difficult to account for non-uniformities, and non-uniformities can result in processing delays, substrate waste, and reduced throughput.

Therefore, there is a need in the art for a reduction in the migration of purge gas from the purge volume to the processing volume of the processing chamber.

### SUMMARY

The present disclosure relates to methods of adjusting uniformity for substrate processing, and related apparatus and systems, for semiconductor manufacturing. In one or more embodiments, a heating power applied to a set of one or more heat sources is adjusted by an adjustment factor.

In one embodiment, a processing chamber is disclosed. The processing chamber includes a chamber body. The chamber body includes an upper body, a lower body, a carrier and feed (CF) ring disposed between the upper body and the lower body, an upper liner, a lower liner, and a substrate support. The lower liner includes an upper venting liner. The upper venting liner includes one or more upper vents, and an internal volume. The internal volume includes a processing volume, and a purge volume. The substrate support is disposed within the internal volume. The upper venting liner is disposed below the substrate support.

In another embodiment, a processing chamber is disclosed. The processing chamber includes a chamber body, an internal volume, and a substrate support. The chamber body includes an upper body, a lower body, a carrier and feed (CF) ring disposed between the upper body and the lower body, an upper liner, and a lower liner. The lower liner includes an upper venting liner. The upper venting liner includes one or more upper vents and a preheat ring. The internal volume includes a processing volume and a purge volume. The substrate support is disposed within the internal volume. The upper venting liner is disposed below the substrate support.

In yet another embodiment, a system for processing substrates is disclosed. The system includes a chamber body, an internal volume, a substrate support, a sensor, and a controller. The chamber body includes an upper body, a lower body, a carrier and feed (CF) ring disposed between the upper body and the lower body, an upper liner, and a lower liner. The lower liner includes an upper venting liner. The upper venting liner includes one or more upper vents. The internal volume includes a processing volume and a purge volume. The substrate support is disposed within the internal volume. The upper venting liner is disposed below the substrate support. The sensor is configured to sense parameters in the internal volume. The controller includes instructions that, when executed, cause a plurality of operations to be conducted. The plurality of operations includes flowing a processing gas into the processing volume and a purge gas into the purge volume; heating the substrate and substrate support; processing a substrate; monitoring the parameters of the substrate and substrate support using sensor readings from the sensors; venting the purge gas and the processing gas from the chamber body; and adjusting a system model based on the sensor readings.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic side cross-sectional view of a processing chamber, according to embodiments.

FIG. 2A is a schematic side cross-sectional view of a processing chamber at cut line 2A-2A, according to embodiments.

FIG. 2B is a schematic top cross-sectional view of a processing chamber at cut line 2B-2B, according to embodiments.

FIG. 2C is a schematic side cross-sectional view of a portion of the processing chamber, according to embodiments.

FIG. 3 is a flow diagram of a method of processing a substrate, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatus and systems for semiconductor processing. In particular, the present disclosure is directed towards epitaxial deposition chambers.

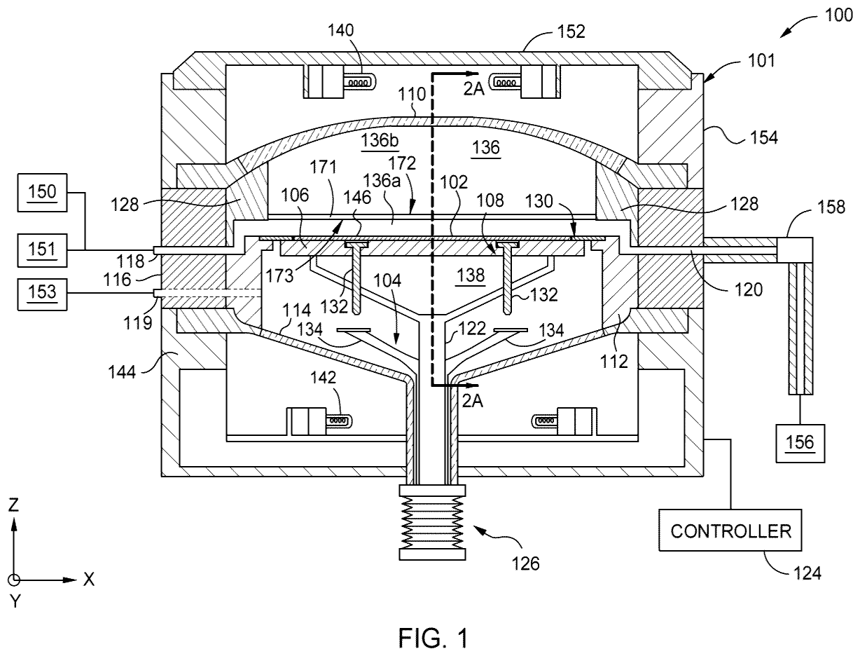

FIG. 1 is a schematic side cross-sectional view of a processing chamber 100. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 146 of the substrate 102.

The processing chamber 100 includes an upper body 154, a lower body 144, and a carrier and feed (CF) ring 116 disposed between the upper body 154 and the lower body 144. The upper body 154, the CF ring 116, and the lower body 144 form at least part of a chamber body 101. Disposed within the chamber body 101 is a substrate support 106, an upper window 110 (e.g., an upper dome, a flat top a concave top, or an upper surface with different contour shapes), a lower window 114 (e.g., a lower dome, a flat surface, a concave surface, or a lower surface with different contour shapes), a plate 171, a plurality of upper lamps 140, and a plurality of lower lamps 142. The upper lamps 140 and lower lamps 142 are configured to heat the substrate 102 and the substrate support 106. The plate 171 (e.g., an isolation plate) includes a first face 172 and a second face 173 opposite the first face 172. The second face 173 faces the substrate support 106. In one or more embodiments, the plate 171 is part of a flow guide structure. In one or more embodiments, the plate 171 is in the shape of a disc or a rectangle.

The substrate support 106 is disposed between the upper window 110 and the lower window 114. The substrate support 106 includes a support face 130 that is configured to support the substrate 102. A lid 152 may include a plurality of sensors (not shown) disposed therein for measuring the temperature within the processing chamber 100 and for measuring parameters of the substrate 102 and/or substrate support 106. The upper window 110 and the lower window 114 are formed of an energy transmissive material, such as quartz.

A processing volume 136 and a purge volume 138 are formed between the upper window 110 and the lower window 114. The processing volume 136 and the purge volume 138 are part of an internal volume defined at least partially by the upper window 110, the lower window 114, an upper liner 128, and at least one lower liner 112. The processing volume 136 is disposed above the substrate support 106. The plate 171 divides the processing volume 136 between the substrate support 106 and the upper window 110 into a lower portion 136a and an upper portion 136b. The lower portion 136a is a processing portion and the upper portion 136b is an isolated portion. The purge volume 138 is disposed below the substrate support 106. In one or more embodiments, the plate 171 is an isolation plate is disposed between and that at least partially physically isolates the upper portion 136b from the lower portion 136a.

The internal volume has the substrate support 106 disposed therein. The substrate support 106 is attached to a shaft 122. The shaft 122 is connected to a motion assembly 126. The motion assembly 126 includes one or more actuators or adjustment devices that provide movement or adjustment for the shaft 122 or the substrate support 106 within the processing volume 136.

The substrate support 106 may include lift pin holes 108 disposed therein. The lift pin holes 108 are sized to accommodate lift pins 132 for lowering and lifting of the substrate 102 to and from the substrate support 106 before or after a deposition process is performed. The lift pins 132 may rest on lift pin stops 134 when the substrate support 106 is lowered from a processing position to a transfer position. The lift pin stops 134 can be coupled to a second shaft 104 through a plurality of arms.

The CF ring 116 includes a process gas inlet 118, a purge gas inlet 119, and one or more gas exhaust outlets 120. In one or more embodiments, the process gas inlet 118 and purge gas inlet 119 are disposed on the opposite side of the CF ring 116 from the one or more gas exhaust outlets 120. The upper liner 128 and the lower liner 112 are disposed on an inner surface of the CF ring 116 and protect the CF ring 116 from reactive gases used during deposition operations or cleaning operations. The gas inlet 118 is configured to flow a gas parallel to the top surface 146 of a substrate 102 disposed within the processing volume 136. The process gas inlet 118 is fluidly connected to one or more processing gas sources 151 and one or more cleaning gas sources 150. The purge gas inlet 119 is fluidly connected to one or more purge gas sources 153. The one or more gas exhaust outlets 120 are fluidly connected to an exhaust pump 156. One or more processing gases supplied using the one or more processing gas sources 151 can include one or more reactive gases (such as one or more sources of silicon (Si), phosphorus (P), or germanium (Ge)) or one or more carrier gases (such as one or more of nitrogen (N₂) or hydrogen (H₂)). One or more cleaning gases supplied using the one or more cleaning gas sources 150 can include one or more of hydrogen chloride (HCl) or chlorine (Cl₂). In one or more embodiments, the one or more processing gases include phospine (PH₃), and the one or more cleaning gases include hydrochloric acid (HCl).

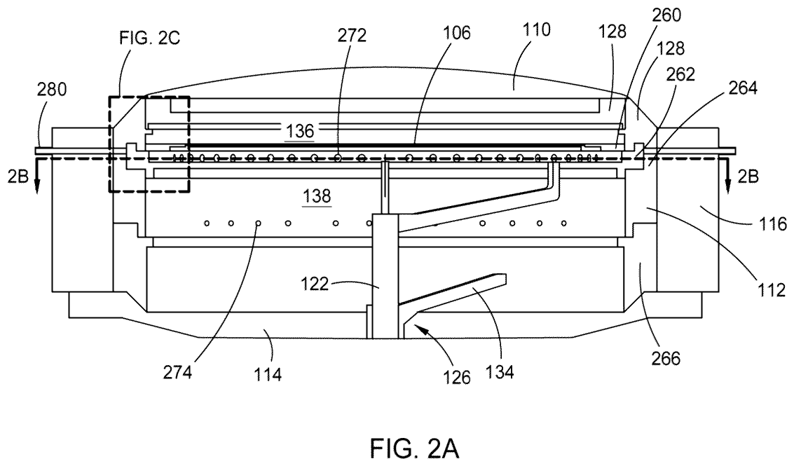

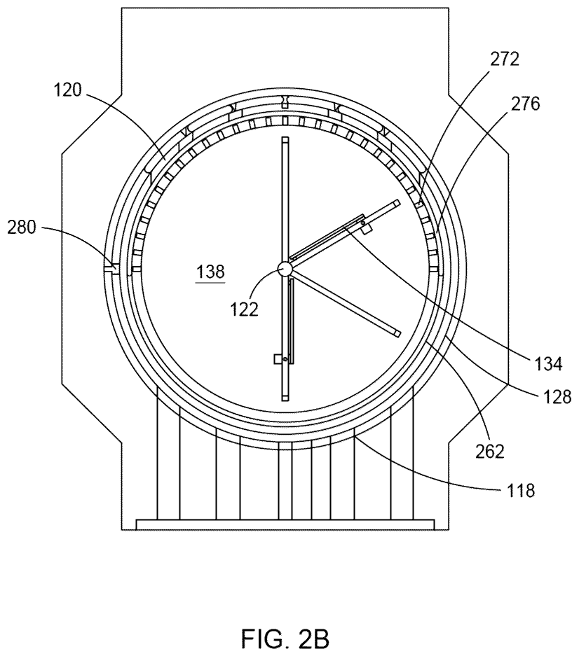

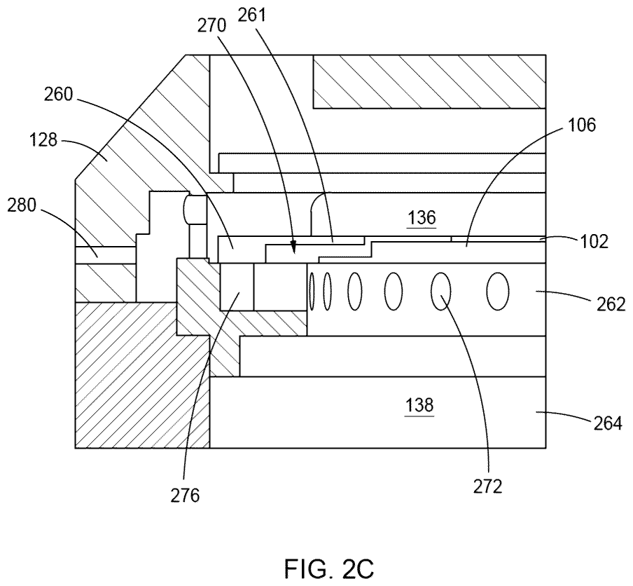

The CF ring 116 may include a cross-flow inlet 280 (shown in FIG. 2A). The cross-flow inlet 280 is configured to flow the processing gas into the processing volume 136. The cross-flow inlet enables edge tunability on the substrate 102, e.g., the cross-flow inlet enable controlled deposition on the edges of the substrate 102.

The one or more gas exhaust outlets 120 are further connected to or include a high-vacuum pump 158. The high-vacuum pump 158 fluidly connects the one or more gas exhaust outlets 120 and the exhaust pump 156. The high-vacuum pump 158 can assist in the controlled deposition of a layer on the substrate 102. In one or more embodiments, the high-vacuum pump 158 is disposed on an opposite side of the processing chamber 100 relative to the process gas inlets 118.

A controller 124 is in communication with the processing chamber 100 and is used to control processes and methods, such as the operations of the methods described herein. The controller 124 can control the sensors in the lid 152, the upper lamps 140 lower lamps 142, and the flow of processing gas and purge gas. The controller 124 can conduct methods to adjust uniformity of the substrate 102 using at least one or the sensors, the upper lamps 140, the lower lamps 142, and the flow of the processing gas and purge gas. The controller 124 is configured to receive data or input as sensor readings from the sensors. The controller 124 is equipped with or in communication with a system model of the processing chamber 100. The system model includes at least a deposition uniformity module and a gas flow module. The system module is a program configured to estimate parameters of the substrate 102 and/or substrate support 106 within the processing chamber 100 throughout the deposition process. The controller 124 is configured to store readings and calculations. The readings and calculations include previous calculated values after the sensor readings are measured by the controller 124 and run through the system model. Therefore, the controller 124 is configured to both retrieve stored readings and calculations as well as save readings and calculations for future use. Maintaining previous readings and calculations enables the controller 124 to adjust the system model over time to reflect a more accurate version of the processing chamber.

The controller 124 may include a central processing unit (CPU) (e.g., a processor), a memory containing instructions, and support circuits for the CPU. The controller 124 controls various items directly, or via other computers and/or controllers. The controller 124 is any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 124 are coupled to the CPU for supporting the CPU. The support circuits include cache, power supplies, clock circuits, input/output circuitry and subsystems, and the like. Operational parameters (e.g., target value(s), reading(s), signal difference(s), signal profile(s), heating power(s) (e.g., applied to one or more of the heat sources), adjustment factor(s), threshold ratio(s), range(s) and/or training range(s) with which the signal difference(s) are compared, a cleaning recipe, and/or a processing recipe) and operations are stored in the memory as a software routine that is executed or invoked to turn the controller 124 into a specific purpose controller to control the operations of the various chambers/modules described herein. The controller 124 is configured to conduct any of the operations described herein. The instructions stored on the memory, when executed, cause one or more of operations of: flowing processing gas and purge gas, heating the substrate 102 and substrate support 106, venting purge gas and processing gas from the chamber body 101, monitoring the parameters of the substrate 102 and substrate support 106 using sensor readings from the sensors, and adjusting the system model based on the sensor readings.

FIG. 2A is a schematic side cross-sectional view of a processing chamber 100 at cut line 2A-2A. FIG. 2B is a schematic top cross-sectional view of a processing chamber 100 at cut line 2B-2B. FIG. 2C is a schematic side cross-sectional view of a portion of the processing chamber 100. The lower liner 112 further includes a preheat ring 260, an upper venting liner 262, a lower venting liner 264, and a base ring 266. The preheat ring 260 includes a flange 261 extending radially inward and extending over a portion of the substrate support 106. The preheat ring 260 may be configured to preheat the substrate support 106 prior to the processing of the substrate 102, or to preheat the substrate support 106 and the substrate 102 while the substrate 102 is supported on the substrate support 106.

The upper venting liner 262 includes one or more upper vents 272. The lower venting liner 264 includes one or more lower vents 274. The upper vents 272 are configured to vent a purge gas from the purge volume 138. The upper vents 272 are fluidly connected by an upper vent conduit 276, which is fluidly connected to the one or more gas exhaust outlets 120. The upper vents 272 are configured to vent purge gas from the purge volume 138 through the one or more gas exhaust outlets 120 via the upper vent conduit 276. A flow path 270 is defined between the flange 261 and the substrate support 106. The flow path 270 is fluidly connected to the upper vent conduit 276. The flow path 270 enables the processing gas to flow across the substrate 102 and vents the processing gas from the processing volume 136 through the one or more gas exhaust outlets 120 via the upper vent conduit 276.

The venting of the purge gas from the purge volume 138 enables the reduction of edge roll off on the substrate 102. Edge roll off may occur when the purge gas from the purge volume 138 migrates into the processing volume 136, causing dilution of the processing gas over the substrate 102, particularly on the edges of the substrate 102. The venting of the processing gas through the one or more gas exhaust outlets 120 via the flow path 270 and upper vent conduit 276 increases the velocity contour of the processing gas across the substrate 102, and in particular at the edges of the substrate 102. The increase in the velocity contour the processing gas at the edges of the substrate 102 increases processing gas diffusion in the processing volume 136, and decreases the velocity of the purge gas migration from the purge volume 138 to the processing volume 136.

Furthermore, the venting of the purge gas through the upper vents 272 reduces the edge roll off by decreasing the velocity of the purge gas migration from the purge volume 138 to the processing volume 136. By venting the purge gas through the upper vents 272, the amount of purge gas, and thus the velocity of the purge gas, migrating from the purge volume 138 to the processing volume 136 is decreased. This allows for the increase in the processing gas velocity and processing gas diffusion near the edges of the substrate 102. The increased processing gas velocity and processing gas diffusion, thus, leads to a decrease in the non-uniformity of the processing gas deposition on the substrate 102. The upper vents 272 may decrease the non-uniformity of the processing gas deposition by about 0.2% to about 0.6%.

The upper vents 272 have a radius of 2 mm to about 20 mm, such as about 3.5 mm to about 5 mm. The lower vents 274 have a radius of about 1 mm to about 10 mm, such as about 1.925 mm. In some embodiments, the upper vents 272 are disposed along the circumference of the upper venting liner 262. In other embodiments, the upper vents 272 are disposed along a portion of the circumference of the upper venting liner 262, e.g., the upper vents 272 are disposed in a semi-or half-circle along the circumference of the upper venting liner 262.

In some embodiments, the preheat ring 260 includes a preheat ring lock gap. The preheat ring lock gap is configured to enable the preheat ring 260 to be secured into position with respect to the substrate support 106. Further, the preheat ring lock gap enables the preheat ring 260 to expand and contract as the temperature within the processing chamber 100 increases and decreases. The preheat ring lock gap has a gap distance of about 5 mm to about 10 mm.

In other embodiments, the preheat ring 260 does not include a preheat ring lock gap. The preheat ring 260 without the preheat ring lock gap may further enable the reduction of edge roll off on the substrate 102. By removing the preheat ring lock gap, a pathway for the purge gas to migrate from the purge volume 138 to the processing volume 136 is removed from the processing chamber 100.

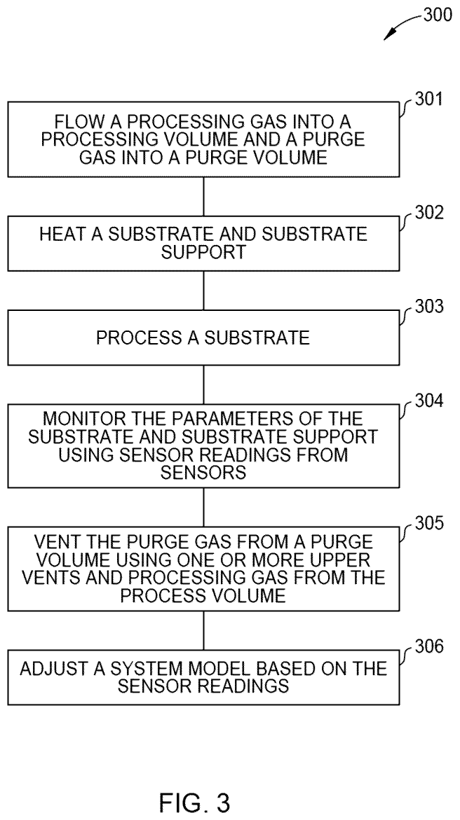

FIG. 3 is a flow diagram of a method 300 of processing a substrate 102. At operation 301, a processing gas is flowed into a processing volume 136 and a purge gas is flowed into a purge volume 138. The processing volume 136 and the purge volume 138 are part of an internal volume defined at least partially by an upper window 110, a lower window 114, an upper liner 128, and at least one lower liner 112 of a processing chamber 100. The processing volume 136 is disposed above a substrate support 106. The purge volume 138 is disposed below the substrate support 106.

At operation 302, a substrate 102 and the substrate support 106 are heated. The substrate 102 is disposed on a substrate support 106. At operation 303, the substrate is processed. The processing of the substrate 102 includes an epitaxial deposition process. During processing, a film is formed on a surface of the substrate 102.

At operation 304, the parameters of the substrate and the substrate support are monitored using sensor readings from sensors. The sensors may be configured to monitor the substrate and substrate support temperature, the epitaxial deposition rate of the process, the thickness of the deposited film, or other parameters. The sensor readings from the sensors provide information regarding the uniformity of the deposited film to the controller 124 to enable the controller 124 to adjust the processing parameters of the epitaxial deposition process to ensure that there is uniform deposition across the surface of the substrate. The sensors include temperature sensors, pressure sensors, or film thickness metrology sensors. The processing parameters may include, among other things, pressure, temperature, processing volume size, gas flow rates, gas composition, species densities, deposition and etch yield, deposition rate, deposition uniformity, deposition selectivity, and anisotropy damage.

At operation 305, the purge gas is vented from the purge volume 138 and the process gas is purged from the process volume 136 using an upper vent conduit 276. The purge gas is vented from the purge volume 138 by flowing through the one or more upper vents 272 and the upper vent conduit 276 to the one or more gas exhaust outlets 120. The processing gas is vented from the processing volume 136 by flowing through a flow path 270 and the upper vent conduit 276 to the one or more gas exhaust outlets 120. In some embodiments, a high-vacuum pump 158 increases the flow rate of the purge gas and the processing gas through the one or more upper vents 272, the flow path 270, and the upper vent conduit 276. The upper vents 272 enable the reduction of edge roll off on the substrate 102 by reducing the migration of purge gas from the purge volume 138 to the process volume 136 and increasing the velocity contour of the processing gas across the substrate 102.

At operation 306, a system model is adjusted based on the sensor readings. The system model may include information including processing cycle time, process gas venting rate, purge gas venting rate, process gas flow rate, purge gas flow rate, substrate and substrate support temperature, deposition rate or other parameters. Based on the sensor readings from the sensors, the controller 124 adjusts the system model to correct for non-uniformity in the deposition of the deposited film. For example, the controller 124 may increase the flow rate of the exhaust pump 156 to further decrease the migration of the purge from the purge volume 138 to the process volume 136, thereby further increasing the velocity contour of the processing gas across the substrate 102 and increasing the uniformity of the deposited film.

In summary, the processing chamber disclosed herein includes a lower liner having an upper vent ring. The upper vent ring includes one or more upper vents configured to vent purge gas from a purge volume to an exhaust via an upper vent conduit. By venting the purge gas through the upper vents, the migration of purge gas from the purge volume to a processing volume is reduced. A reduction in the migration of purge gas to the processing volume may increase the processing gas velocity and diffusion, which may increase the uniformity of deposition on the substrate.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a chamber body, the chamber body comprising:
a lower liner, comprising an upper venting liner, the upper venting liner comprising:
one or more upper vents;
an internal volume, comprising:
a processing volume; and
a purge volume; and
a substrate support disposed within the internal volume, wherein the upper venting liner is disposed below the substrate support.

2. The processing chamber of claim 1, wherein the one or more upper vents have a radius of 2 mm to about 20 mm.

3. The processing chamber of claim 1, wherein the upper vents are disposed along a circumference of the upper venting liner.

4. The processing chamber of claim 1, further comprising an isolation plate disposed between an upper portion of the processing volume and a lower portion of the processing volume.

5. The processing chamber of claim 4, wherein the portion of the upper venting liner is a semi-circular portion of the upper venting liner.

6. The processing chamber of claim 1, wherein the lower liner further comprises a lower venting liner, the lower venting liner comprises one or more lower vents.

7. The processing chamber of claim 6, wherein the lower vents have a radius of about 1 mm to about 10 mm.

8. A processing chamber, comprising:
a chamber body, the chamber body comprising:
a lower liner, comprising an upper venting liner, the upper venting liner comprising:
one or more upper vents; and
a preheat ring;
an internal volume, comprising:
a processing volume; and
a purge volume; and
a substrate support disposed within the internal volume, wherein the upper venting liner is disposed below the substrate support.

9. The processing chamber of claim 8, wherein the preheat ring comprises a flange extending radially inward and extending over a portion of the substrate support.

10. The processing chamber of claim 8, wherein the preheat ring includes a preheat ring lock gap.

11. The processing chamber of claim 10, wherein the preheat ring lock gap comprises a gap distance of about 5 mm to about 10 mm.

12. The processing chamber of claim 8, wherein the one or more upper vents have a radius of 2 mm to about 20 mm.

13. The processing chamber of claim 8, wherein the upper vents are disposed along a circumference of the upper venting liner.

14. The processing chamber of claim 8, wherein the upper vents are disposed along a semi-circular portion of the upper venting liner.

15. A system for processing substrates, the system comprising:
a chamber body, the chamber body comprising:
a lower liner, comprising an upper venting liner, the upper venting liner comprising:
one or more upper vents;
an internal volume, comprising:
a processing volume; and
a purge volume;
a substrate support disposed within the internal volume, wherein the upper venting liner is disposed below the substrate support;
a sensor configured to sense parameters in the internal volume; and
a controller comprising instructions that, when executed, cause a plurality of operations to be conducted, the plurality of operations comprising:
flowing a processing gas into the processing volume and a purge gas into the purge volume;
heating the substrate and substrate support;
processing a substrate;
monitoring the parameters of the substrate and substrate support using sensor readings from the sensors;
venting the purge gas and the processing gas from the chamber body; and
adjusting a system model based on the sensor readings.

16. The system of claim 15, wherein the one or more upper vents have a radius of 2 mm to about 20 mm.

17. The system of claim 15, wherein the upper vents are disposed along a circumference of the upper venting liner.

18. The system of claim 15, wherein the upper vents are disposed along a portion of the upper venting liner.

19. The system of claim 18, wherein the portion of the upper venting liner is a semi-circular portion of the upper venting liner.

20. The system of claim 15, further comprising a preheat ring comprising a flange extending radially inward and extending over a portion of the substrate support.
